(19) United States
(12) Patent Application Publication
(10) Pub. No.: US 2012/0229999 A1
(43) Pub. Date: Sep. 13, 2012

(54) CIRCUIT BOARD CLAMPING MECHANISM

(76) Inventor: Rafiqul Hussain, Fremont, CA (US)

(21) Appl. No.: 13/042,651

(22) Filed: Mar. 8, 2011

(51) Int. Cl. H05K 7/00; H05K 13/00

(52) U.S. Cl. 361/783; 361/784; 29/592.1

(57) ABSTRACT

Methods and apparatus for clamping a first circuit board against a member are provided where the first circuit board has a first side and a second side opposite the first side. The method includes engaging an elastomeric member of a clamping member with the first side of the first circuit board to compliantly bear against the first side of the first circuit board whereby the second side of the circuit board is clamped against the member.

### BACKGROUND OF THE INVENTION

1. Field of the Invention

This invention relates generally to semiconductor processing, and more particularly to apparatus for and methods of clamping circuit boards to other members.

2. Description of the Related Art

A typical conventional packaged semiconductor chip consists of a laminate of several layers of different materials. From bottom to top, a typical package consists of a base or carrier substrate, a die underfill material, an array of solder joints and the silicon die. For some designs, a thermal interface material and a lid or heat spreader top off the stack. Each of these layers generally has a different coefficient of thermal expansion (CTE). In some cases, the coefficients of thermal expansion for two layers, such as the underfill material and the silicon die, may differ by a factor of ten or more. Materials with differing coefficients of thermal expansion strain at different rates during thermal cycling. The differential strain rates tend to produce warping of the package substrate and the silicon die. If the warping is severe enough, several undesirable things can occur. First, the carrier substrate can be warped to a point where some of solder joints delaminate and cause electrical failure. Second, and in the case of lid-type designs, the thermal interface material can be stretched to the point of delamination from either the semiconductor chip, the lid or both. The thermal resistance of the delaminated area can increase substantially resulting in significant heat buildup in that area which can damage the chip.

Due to a variety of mechanisms, a given semiconductor chip package substrate or other type of circuit board may exhibit a warpage in one direction or another at room temperature. If the package substrate is subsequently ramped up in temperature, the warpage may disappear or even progress in the opposite direction depending upon the temperature and the mechanical properties of the substrate. It follows then that many circuit boards or semiconductor chip package substrates may exhibit a pronounced warpage at room temperature. However, such circuit boards and other types of substrates must routinely undergo certain types of processing steps such as testing, component placement and others prior to ultimate completion of such circuit boards or packages. Thus, there may be many steps where the semiconductor chip package substrate must be mounted in a fixture or socket of some sort and subjected to some type of component placement or testing process.

The room temperature warpage of such circuit boards is addressed conventionally by clamping the circuit board or other type of substrate against a socket, for example, using a clamping member that consists of a metal block that has a peripheral load surface and an internal space designed to provide clearance for a semiconductor chip flip-chip or otherwise mounted to the circuit board and perhaps components that are peripherally spaced around the semiconductor chip. The clamping block is designed to engage the upper surface of the circuit board and through the application of force flatten the circuit board while the circuit board undergoes the fabrication or testing step. The desire to at least temporarily flatten the circuit board, particularly for a ball grid array board, springs from the need to sometimes establish ohmic contact between the input/output structures of the circuit board such as solder balls, and input/output structures of the test board such as fixed pins. With warped circuit boards, there may be significant differences in the vertical positions of the solder balls relative to the fixed pins of the test board. The temporary flattening will tend to make the various solder balls fall into relatively co-planar position so that uniform ohmic contact is established across the socket.

Some manufacturers of certain types of conventional fab tools provide highly specialized types of clamping fixtures that are suitable for holding a semiconductor chip package while in a given tool. For example, Panasonic provides a fixture for holding a semiconductor chip package during a passive components placement process. Datacon provides a fixture for use in a direct placement machine while DEK provides a dedicated fixture for use in a solder printing machine. These conventional machine-specific fixtures provide temporary flattening of the otherwise warped package substrate. Once the substrate is removed from the particular machine, the previous warping state will tend to return quickly. Conventional clamping fixtures tend to use vacuum systems in order to provide the requisite clamping force and thus involve a certain level of system and operation complexity.

A difficulty associated with the conventional clamping techniques is the fact that somewhat significant bending moments must be applied to the circuit board during the duration of the clamping. This follows from the fact that since the circuit board is in a warped state prior to the clamping process, clamping necessarily results in the imposition of significant moments in order to induce the requisite flattening. Depending upon the overall ductility of the circuit board, such bending moments may impose significant stresses within the circuit board. Often the bending stresses are imposed prior to substrate heating and the attendant reduction in stiffness due to such heating.

The present invention is directed to overcoming or reducing the effects of one or more of the foregoing disadvantages.

### SUMMARY OF EMBODIMENTS OF THE INVENTION

In accordance with one aspect of an embodiment of the present invention, a method of clamping a first circuit board against a member is provided where the first circuit board has a first side and a second side opposite the first side. The method includes engaging an elastomeric member of a clamping member with the first side of the first circuit board to compliantly bear against the first side of the first circuit board whereby the second side of the circuit board is clamped against the member.

In accordance with another aspect of an embodiment of the present invention, a clamping member adapted to clamp a first circuit board against a member is provided where the first circuit board has a first side and a second side opposite the first side. The clamping includes a body that has a first side and a second side opposite the first side, and an elastomeric member coupled to the second side of the body and adapted to compliantly bear against the first side of the first circuit board and clamp the second side of the circuit board against the member.

In accordance with another aspect of an embodiment of the present invention, an apparatus is provided that includes a first circuit board that has a socket and a clamping member adapted to clamp a second circuit board against the socket. The clamping member includes a body that has a first side and a second side opposite the first side, and an elastomeric member coupled to the second of the body and adapted to compliantly bear against the first side of the first circuit board and clamp the second side of the circuit board against the member.

### BRIEF DESCRIPTION OF THE DRAWINGS

The foregoing and other advantages of the invention will become apparent upon reading the following detailed description and upon reference to the drawings in which:

FIG. 1 is a pictorial view of an exemplary embodiment of a semiconductor chip device that includes a semiconductor chip mounted to a circuit board;

FIG. 2 is a sectional view of FIG. 1 taken at section 2-2;

FIG. 3 is a sectional view depicting the semiconductor chip device seated on a conventional test circuit board socket;

FIG. 4 is a sectional view like FIG. 3 but depicting conventional clamping of the circuit board against the socket using a flattening type clamping body;

FIG. 5 is a sectional view depicting the exemplary semiconductor chip device seated in an exemplary socket and circuit board combination and with an exemplary clamping device positioned over the semiconductor chip device;

FIG. 6 is a sectional view like FIG. 5 but depicting a clamping of the circuit board using the exemplary clamping device;

FIG. 7 is a pictorial view of an exemplary clamping body with an exemplary elastomeric member;

FIG. 8 is a pictorial view of an alternate exemplary clamping body and elastomeric member;

FIG. 9 is a pictorial view of an another alternate exemplary embodiment of a clamping body and elastomeric member;

FIG. 10 is a pictorial view of an another alternate exemplary embodiment of a clamping body and elastomeric member;

FIG. 11 is a sectional view of an exemplary semiconductor chip device seated in an alternate exemplary circuit board socket utilizing an exemplary clam shell clamping member;

FIG. 12 is a sectional view of an alternate exemplary semiconductor chip device exhibiting an upward warpage;

FIG. 13 is a sectional view of an alternate exemplary embodiment of a clamping device that includes plural clamping bodies joined together;

FIG. 14 is a flow chart depicting an exemplary clamping and testing process;

FIG. 15 is an exploded pictorial view of an exemplary clamping device used to secure a semiconductor chip device to a circuit board carrier or boat; and

FIG. 16 is a pictorial view of an exemplary automated test equipment console.

### DETAILED DESCRIPTION OF SPECIFIC EMBODIMENTS

Various embodiments of a clamping mechanism suitable to clamp a circuit board against another member, such as a circuit board socket are described herein. One example includes a clamping member body and an elastomeric member coupled to the body. The elastomeric member may include one or more interior spaces to provide clearance for components positioned on the circuit board, such as semiconductor chips and/or passive components. The elastomer member provides a compliant force surface. A technical goal is to provide clamping but not necessarily flattening of warped circuit boards. Additional details will now be described.

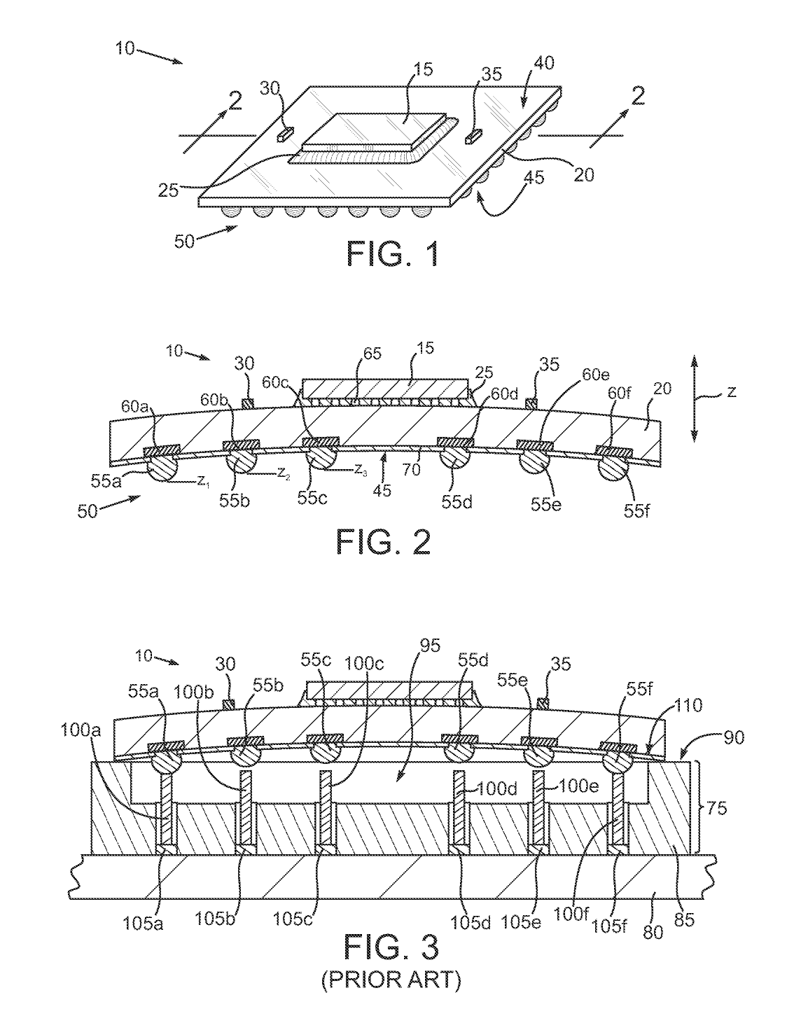

In the drawings described below, reference numerals are generally repeated where identical elements appear in more than one figure. Turning now to the drawings, and in particular to FIG. 1 therein is shown a pictorial view of an exemplary embodiment of a semiconductor chip device 10 that may include a semiconductor chip 15 mounted to a circuit board 20. To lessen the effects of differing coefficients of thermal expansion of the constituents of the device 10, an underfill material 25 may be positioned between the semiconductor chip 15 and the circuit board 20. In FIG. 1 the underfill material 25 is visible as a bead surrounding the perimeter of the semiconductor chip 15. In addition to the semiconductor chip 15, the circuit board 20 may be provided with additional components, a couple of which are labeled 30 and 35. The components 30 and 35 may be passive elements, such as capacitors, inductors, resistors or other types of circuit devices may be much more numerous than two. These components 30 and 35 are mounted on the upper surface 40 of the circuit board 20 but may also be mounted on the under side 45 thereof. A ball grid array 50 may be provided on the lower side 45 of the circuit board 20 to provide input/output structures that enable the circuit board 20 to electrically interface with other circuit devices such as another circuit board or other. The ball grid array 50 consists of plural solder balls that are designed to establish metallurgical bonds with corresponding structures on another device and by way of a solder reflow process. Optionally, a land grid array, pin grid array or other type of input/output array may be used.

The clamping devices disclosed herein are not dependent on particular functionalities of either the semiconductor chip 15 or the circuit board 20. Thus, the semiconductor chip 15 may be any of a myriad of different types of circuit devices used in electronics, such as, for example, microprocessors, graphics processors, combined microprocessor/graphics processors, application specific integrated circuits, memory devices or the like, and may be single or multi-core or even stacked with additional dice. The semiconductor chip 15 may be constructed of bulk semiconductor, such as silicon or germanium, or semiconductor on insulator materials, such as silicon-on-insulator materials. The semiconductor chip 15 may be flip-chip mounted to the circuit board 20 and electrically connected thereto by solder joints or other structures (not visible in FIG. 1 but shown in subsequent figures).

The circuit board 20 may be a semiconductor chip package substrate, a circuit card, or virtually any other type of printed circuit board. Although a monolithic structure could be used for the circuit board 20, a more typical configuration will utilize a build-up design. In this regard, the circuit board 20 may consist of a central core upon which one or more build-up layers are formed and below which an additional one or more build-up layers are formed. The core itself may consist of a stack of one or more layers. One example of such an arrangement may be termed a so called “2-2-2” arrangement where a single-layer core is laminated between two sets of two build-up layers. If implemented as a semiconductor chip package substrate, the number of layers in the circuit board 20 can vary from four to sixteen or more, although less than four may be used. So-called “coreless” designs may be used as well. The layers of the circuit board 20 may consist of an insulating material, such as various well-known epoxies, interspersed with metal interconnects. A multi-layer configuration other than buildup could be used. Optionally, the circuit board 20 may be composed of well-known ceramics or other materials suitable for package substrates or other printed circuit boards. If the circuit board 20 is implemented as a package, lid or lidless designs may be used.

Attention is now turned to FIG. 2, which is a sectional view of FIG. 1 taken at section 2-2. Before turning to FIG. 2 in earnest, it should be noted that section 2-2 of FIG. 1 passes through the semiconductor chip 15, the circuit board 20 and the other components 30 and 35. With that backdrop, attention is now turned to FIG. 2. A few of the solder balls of the ball grid array 50 are shown in section and labeled 55a, 55b, 55c, 55d, 55e and 55f. The balls 55a, 55b, 55c, 55d, 55e and 55f are connected to respective conductor pads 60a, 60b, 60c, 60d, 60e and 60f, which are formed in the underside 45 of the circuit board 20. The conductor pads 60a, 60b, 60c, 60d, 60e and 60f may be part of an outermost metallization layer of what may be multiple layers of metallization interconnected by vias or other structures (not shown) within the body of the circuit board 20. Such metallization structures would provide electrical pathways between the conductor pads 60a, 60b, 60c, 60d, 60e and 60f and plural solder joints 65 which electrically connect the circuit board 20 to the semiconductor chip 15 which, in this case is in a flip-chip mounted orientation. Portions of each of the solder balls 55a, 55b, 55c, 55d, 55e and 55f project through corresponding openings in a solder mask 70 formed on the underside 45 of the circuit board 20. The solder mask 70 may be composed of well-known solder mask materials. The conductor pads 60a, 60b, 60c, 60d, 60e and 60f may be composed of a variety of conductor materials, such as aluminum, copper, silver, gold, titanium, refractory metals, refractory metal compounds, alloys or laminates of these or the like. The solder balls 55a, 55b, 55c, 55d, 55e and 55f and the plural solder joint 65 may be composed of various lead-based or lead-free solders. An exemplary lead-based solder may have a composition at or near eutectic proportions, such as about 63% Sn and 37% Pb. Lead-free examples include tin-silver (about 97.3% Sn 2.7% Ag), tin-copper (about 99% Sn 1% Cu), tin-silver-copper (about 96.5% Sn 3% Ag 0.5% Cu) or the like.

The circuit board 20 is depicted with a downward warpage in FIG. 2. The skilled artisan will appreciate that the direction, that is downward or upward, the severity and the symmetry of the warpage of the circuit board 20 will depend upon a large number of factors, such as the composition of the insulating portions of the circuit board 20, the layout and sizes of various metallization layers (not shown) within the circuit board 20 as well as the size and stiffness of the semiconductor chip 15 and the size and mechanical properties of the underfill material layer 25. In addition, the direction and severity of the warpage will be dependent upon the temperature of the circuit board 20. Assume for the purposes of this illustration that the circuit board 20 is depicted at room temperature and with the downward warpage state as shown. Because of the warpage, the solder balls 55a, 55b and 55c are positioned at respective elevations z₁, z₂ and z₃ relative to the z-axis. The same is true for the solder balls 55d, 55e and 55f albeit in a mirror image. The differences in vertical positions of the solder balls 55a, 55b and 55c present difficulties for establishing reliable electrical contact during various types of electrical testing necessary to establish the functionality of the semiconductor chip device 10. This testing difficulty is depicted in FIG. 3. FIG. 3 is a sectional view depicting the semiconductor chip device 10 seated in a conventional socket 75 that may be mounted to a circuit board 80, which may be a system board, a load board, or other type of circuit board. The socket 75 includes a socket body 85 with a peripheral top surface 90. The body includes an interior space 95. A plurality of I/O pins 100a, 100b, 100c, 100d, 100e and 100f project upwardly from the body 85 and into the interior space 95. The pins 100a, 100b, 100c, 100d, 100e and 100f are designed to establish ohmic contact with the solder balls 55a, 55b, 55c, 55d, 55e and 55f, respectively. Lower ends of the pins 100a, 100b, 100c, 100d, 100e and 100f are connected to corresponding conductor pads or structures 105a, 105b, 105c, 105d, 105e and 105f in the socket body 85. The conductor structures 100a, 100b, 100c, 100d, 100e and 100f are connected to other metallization traces or structures in and/or on the circuit board 80 but are not shown. Note that due to the warpage of the circuit board 20, only the peripheral edge 110 thereof seats on the peripheral surface 90 of the socket body 85. Due to the staggered vertical positions z₁, z₂ and z₃ of the solder balls 55a, 55b, 55c, 55d, 55e and 55f, the outermost balls 55a and 55f readily make contact with the pins 105a and 105f but the other balls 55b, 55c, 55d and 55e are not in contact with the pins 105b, 105c, 105d and 105e.

A conventional remedy to bring the solder balls 55b, 55c, 55d and 55e into contact with pins 105b, 105c, 105d and 105e is depicted in FIG. 4. Here, a conventional clamping member 115 is pressed against the upper surface 40 of the circuit board 20 with sufficient force to essentially flatten the circuit board 20 so that the solder balls 55a and 55f remain in contact with their corresponding pins 100a and 100f and additionally the solder balls 55b, 55c, 55d and 55e are depressed downward and brought into contact with their corresponding pins 105b, 105c, 105d and 105e. The conventional clamping member 115 is provided with a peripheral load surface 120 that is designed to seat on the upper surface 40 of the circuit board 20. A central space 125 is provided in the clamping member 115 in order to accommodate the semiconductor chip 15 and the circuit elements 30 and 35.

As noted above in the Background section hereof, a difficulty associated with conventional circuit board clamping such as that depicted in FIG. 4 is that the circuit board 20 is subjected to significant bending stresses prior to heating by way of device operation testing etc. which would act to soften and increase the ductility of the circuit board 20 and thus lessen the potentially deleterious effects of such low temperature bending stresses.

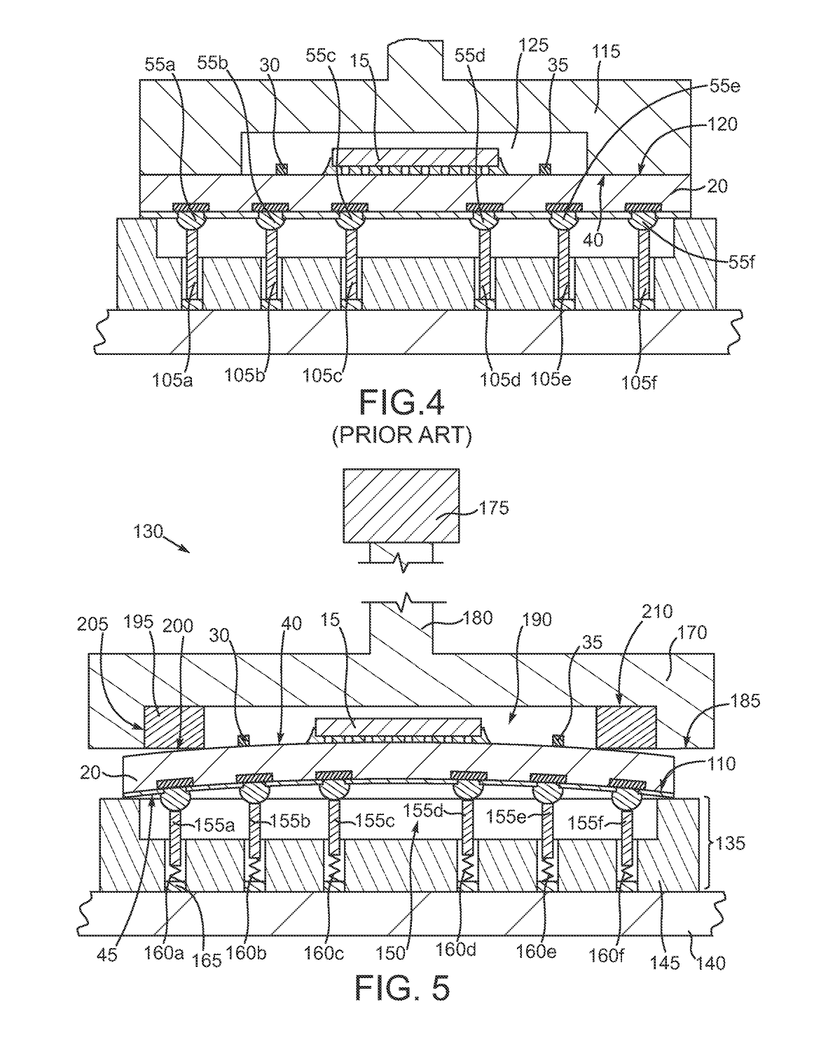

An exemplary embodiment of a clamping mechanism 130 designed to provide less stressful clamping is illustrated in section in FIG. 5. The clamping mechanism 130 may be used to clamp virtually any type of circuit board, with or without a semiconductor chip resident thereon, against some other object, such as socket of a system board, a test board, a substrate carrier or boat or other object. Here, the semiconductor chip device 10 will be used to describe features of the clamping mechanism 130. FIG. 5 shows the semiconductor chip device 10 seated in a socket 135 of a circuit board 140. The circuit board 140 may be a system board, a testing system board, a load board, a peripheral card, a board of an automated test equipment console or the like. The socket 135 may include a socket body 145 and an interior space 150. The socket body 145 includes an upper peripheral seating surface 155 designed to receive the peripheral portion 110 of the circuit board 20. The socket 135 may be composed of various types of insulating materials, such as liquid crystal polymers, fiberglass resin materials, well-known plastics or the like. If composed of plastic materials, the socket body 145 may be formed by injection molding, machining or other well-known material shaping techniques. The socket body 145 includes plural conductor pins 155a, 155b, 155c, 155d, 155e and 155f, which project upwardly into the interior space 150 and are designed to establish ohmic contact with the solder balls 55a, 55b, 55c, 55d, 55e and 55f of the circuit board 20. To accommodate the staggered vertical positions of the solder balls 55a, 55b, 55c, 55d, 55e and 55f, the pins 155a, 155b, 155c, 155d, 155e and 155f are spring-biased by way of biasing members 160a, 160b, 160c, 160d, 160e and 160f. The biasing members 160a, 160b, 160c, 160d, 160e and 160f are electrically connected to respective conductor pads only one of which is labeled 165. The conductor pads 165 may be connected to various metallization structures in or on (not shown) the circuit board 140. The solder balls 55a and 55f, which have the lowest vertical position of the depicted solder balls 55a, 55b, 55c, 55d, 55e and 55f, depress the corresponding pins 155a and 155f and thus the spring members 160a and 160f to a greater extent than the other pins 155b, 155c, 155d and 155e.

The clamping member 130 is designed to hold the circuit board 20 of the semiconductor chip device 10 in position in the socket 135 while enabling the circuit board 20 to remain in its room temperature or thereabouts warped state, and thus without imposing the types of room temperature bending stresses associated with the flattening of the circuit board 20 using the conventional clamping member 115 as shown in FIG. 4. Here, the clamping device 130 includes a clamping body 170 that may be connected to an actuator 175 by way of a shaft 180 or other member. The shaft 180 may be of such length that it is shown broken. The actuator 175 may be a pneumatic cylinder, a linear electric motor, or virtually any other type of mechanism capable of providing movement of the clamping member body 170 along the z-axis. Even a simple rack and pinion arrangement might be used for the actuator 175. The clamping member body 170 may be provided with a downwardly facing peripheral surface 185. Laterally inward from the peripheral surface 185, the body 170 may be provided with an interior space 190. The interior space 190 is sized to provide clearance for the semiconductor chip 15 and the other components 30 and 35. The clamping member body 170 may be composed of various materials, such as aluminum, stainless steel, well-known plastics or the like. Corrosion resistance is a desirable property.

Unlike the conventional clamping member 115 depicted in FIG. 4, which includes a large metal peripheral seating surface 120, the exemplary clamping member body 170 includes an elastomeric member 195 that includes a lower seating surface 200 designed to provide compliant contact with the upper surface 40 of the circuit board 20. In this illustrative embodiment, the elastomeric member 195 is connected to an interior peripheral wall 205 of the opening 190 and to a portion of a lower surface 210 of the clamp member body 170. The elastomeric member 195 may be secured to the clamping member body 170 by way of adhesives, by inherent bonding properties of the elastomeric member 195, by screws or other fasteners or connection devices.

The elastomeric member 195 is designed to provide compliant contact with the surface 40 of the circuit board 20. A very high resistivity in the range of say 10⁶ to 10⁹ ohms is desirable to prevent damage to circuits. A variety of materials may be used for the elastomeric member 195 and any alternatives disclosed herein, such as natural or synthetic rubbers, polyurethane or polyurethane foam supplied by 3M, or the like. As used herein, the term “elastomeric” is intended to encompass materials exhibiting elastic deformation, but not necessarily exhibiting particular percentages of elastic deformation from a relaxed state. Even a polymer or other material that exhibits plastic deformation may be used as the elastomeric member 195 and any disclosed alternatives. A relatively more flexible circuit board 20, such as a coreless design, may call for a less elastic elastomeric member 195. Conversely, a relatively less rigid circuit board 20 composed of ceramics or perhaps organics with large numbers of solder balls, may suggest usage of a less elastic elastomeric member 195.

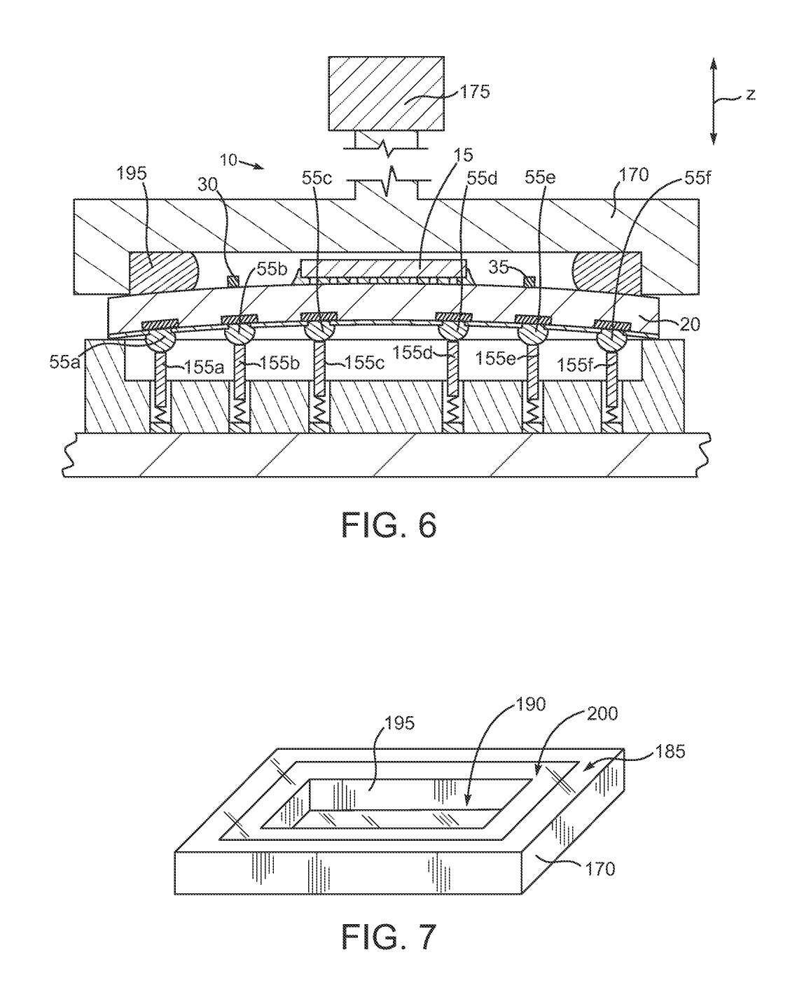

The clamping action of the clamping device 130 will be described now in conjunction with FIGS. 5 and 6. FIG. 5 depicts the clamping member body 170 resting on but applying little if any force to the circuit board 20. Here, the actuator 175 is activated to move the clamping member body 170 downward along the z-axis to compress the elastomeric member 195 against the upper surface 40 of the circuit board 20. As the clamping member body 170 is moved toward the circuit board 20, the elastomeric member engages the sloping upward surface 40 of the circuit board 20 and compresses compliantly against it producing a bulging of the elastomeric member 195 inward toward the circuit elements 30 and 35 and the semiconductor chip 15. Thus, the clamping member body 170 clamps the underside 45 of the circuit board 20 against the socket 135. The elastomeric member 195 applies enough force to hold the circuit board 20 in position without changing the warpage state thereof, in this case substantially non-planar, and without necessarily making metal to insulating surface contact with the circuit board 20 which might otherwise cause surface damage. In other words, the elastomeric member 195 provides a relatively compliant and soft seating surface against the circuit board 20. In addition, the elastomeric member 195 may exhibit an inherent tackiness which prevents lateral jostling of the circuit board 20. The spring-biased pins 155a, 155b, 155c, 155d, 155e and 155f accommodate for the staggered vertical positions of the solder balls 55a, 55b, 55c, 55d, 55e and 55f so that the circuit board need not be flattened in order to establish sufficient ohmic contact for performing electrical testing on the semiconductor chip device 10.

Additional details of the clamping member body 170 may be understood by referring now to FIG. 7, which is a pictorial view of the clamping member body 170 flipped over from its orientation in FIG. 6 to reveal the internal space 190, the elastomeric member 195 and the seating surface 200 thereof. The clamping member body 170 and the elastomeric member 195, may be provided with footprints that generally track the footprint of the circuit board 20. Here, the member body 170 and the elastomeric member 195 may have generally rectangular footprints to match a generally rectangular footprint circuit board 20. However, virtually any shape of circuit board 20 (see FIGS. 1, 5 and 6) may be encountered and thus myriad types of footprints for the member body 170 and the elastomeric member 195 may be used. In this illustration, the seating surface 200 of the elastomeric member 195 and the downward peripheral surface 185 of the member body 170 may be relatively coplanar. Depending upon the size of the circuit board 20 shown in FIGS. 5 and 6, and the amount of downward force applied by the actuator 175 depicted in FIGS. 5 and 6, only the peripheral seating surface 200 of the elastomeric member 195 may actually contact the circuit board shown in FIGS. 5 and 6. However, it may be that some portion of the peripheral surface 185 of the member body 170 also contacts the circuit board 20.

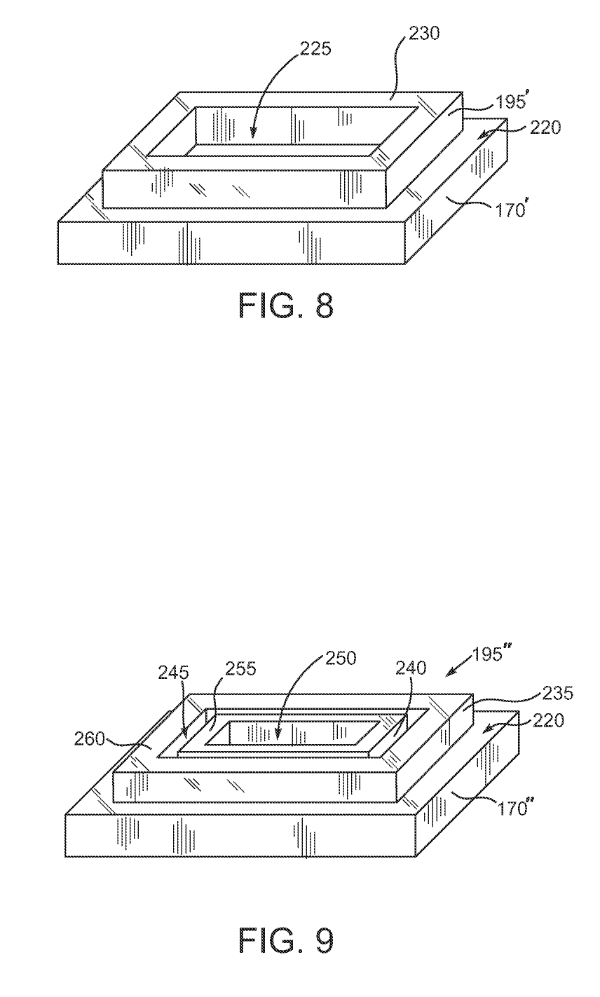

An alternate exemplary embodiment of a clamping member body 170′ may be understood by referring now to FIG. 8, which is a pictorial view. In this illustrative embodiment, the clamping member body 170′ includes a seating surface 220. An alternate exemplary elastomeric member 195′ projects upwardly from the seating surface 220. The elastomeric member 195′ may include an interior space 225 and a peripheral seating surface 230. The peripheral seating surface 230 is designed to seat on and engage the, for example, upper surface 40 of the circuit board 20 depicted in FIGS. 5 and 6 while the interior space 225 provides clearance for the semiconductor chip 15 and the circuit components 30 and 35 also shown in FIGS. 5 and 6. In this way, clamping may be applied without any of the actual clamping member body 170′ contacting the circuit board 20. Again, the footprints of both the clamping member body 170′ and the elastomeric member 195 may be tailored to a particular footprint for the circuit board 20.

Another alternate exemplary embodiment of a clamping member body 170″ may be understood by referring now to FIG. 9, which is a pictorial view. Like the embodiments depicted in FIGS. 7 and 8, the clamping member body 170″ is shown flipped over from the orientation it would have if seated on the circuit board 20 depicted in FIGS. 5 and 6. The clamping member body 170″ includes a peripheral surface 220 and an elastomeric member 195″ that projects upwardly from the surface 220. The elastomeric member 195″ includes a first frame portion 235 and a second frame portion 240 nested within the first frame portion 235 and separated therefrom by a trench 245. The frame portion 240 includes an interior space 250. The interior space 250 is designed to allow clearance for the semiconductor chip 15 depicted in FIGS. 5 and 6. The frame portion 240 includes a peripheral seating surface 255 that is designed to seat on the upper surface 40 of the circuit board 20 depicted in FIGS. 5 and 6 lateral to the semiconductor chip 15. The trench 245 is designed to provide clearance for the circuit components 30 and 35 and the frame portion 235 includes a peripheral seating surface 260 that is designed to seat on the upper surface 40 of the circuit board 20 much like the peripheral surfaces 200 and 230 of the elastomeric members 195 and 195′ depicted in FIGS. 7 and 8.

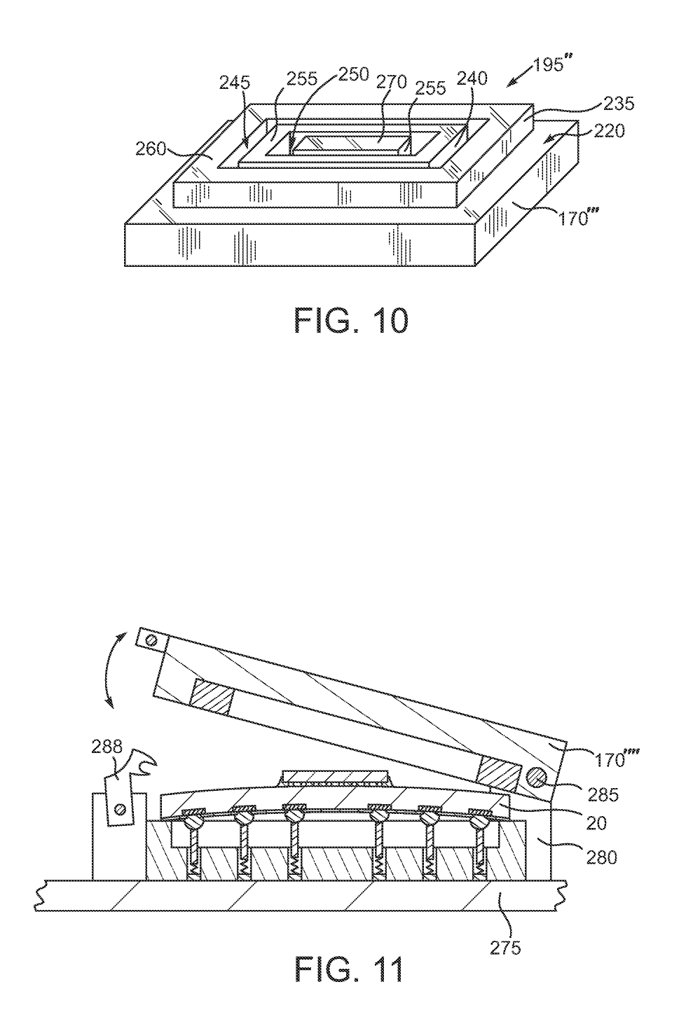

Another alternate exemplary embodiment of a clamping member 170′″ may be understood by referring now to FIG. 10, which is a pictorial view. The clamping member body 170′″ may be substantially identical to the clamping member body 170″ and thus include the surface 220 from which the elastomeric member 195″ projects, a frame portion 235 and an internally nested frame portion 240. However, in this illustrative embodiment, an elastomeric pad 265 may be positioned within the interior space 250 of the frame portion 240 and include a seating surface 270 that is designed to seat on and compliantly engage the semiconductor chip 15 depicted in FIGS. 5 and 6. The usage of such a compliant seating surface 270 for the semiconductor chip 15 may be useful in circumstances where the warpage of the circuit board 20 is severe enough that even the z-axis play of the pins 155a, 155b, 155c, 155d, 155e and 155f of the socket 135 shown in FIGS. 5 and 6 may not be sufficient to establish ohmic contact between the pins 155a, 155b, 155c, 155d, 155e and 155f and the solder balls 55a, 55b, 55c, 55d, 55e and 55f. If desired, the thermal conductivity of the member 265 may be enhanced by infusing it with additives, such as aluminum or copper particles, so that heat may be transferred from the semiconductor chip 15 through the member 265 for devices where the semiconductor chip 15 dissipates enough power that thermal management is required.

As mentioned briefly above, any of the disclosed embodiments of the clamping member body may be brought into contact with the circuit board using a variety of mechanisms. For example, and as shown in FIG. 11, a clamping member body 170″″ may be configured like the clamping member body 170 or any of the other embodiments described elsewhere herein but pivotally mounted to a circuit board 275 and operable to pivot down into engagement with the circuit board 20 in a clam shell like configuration as shown. Here, the clamping member body 170″″ may be pivotally connected to a bracket 280 by way of a pivot pin 285. The bracket 280 may be connected to the circuit board 275 or other structure. A latch 288 may be used to secure the body 170″″.

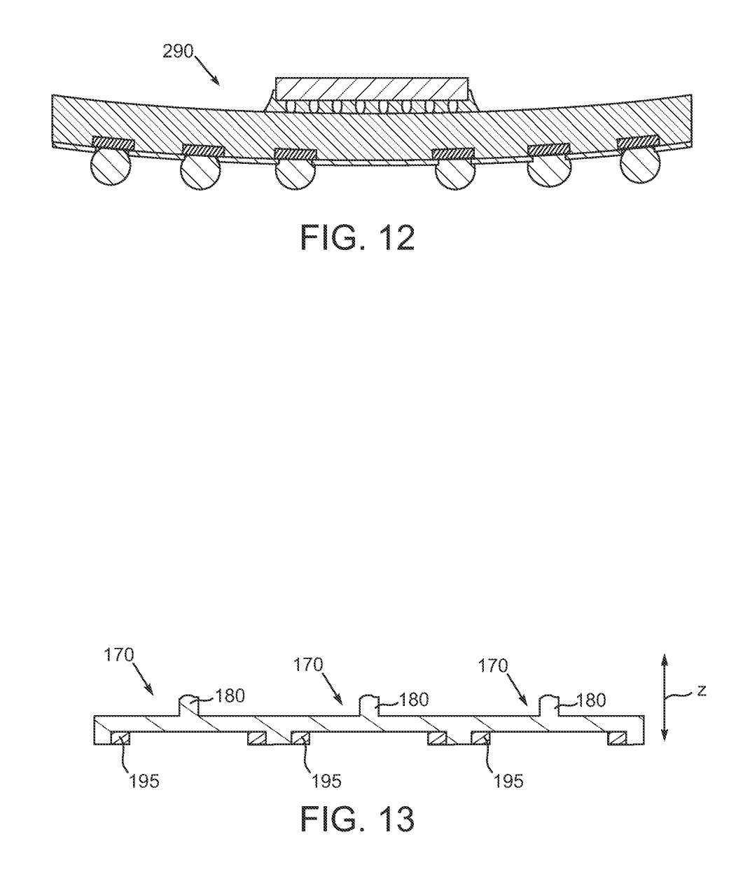

FIG. 12 is a sectional view of another exemplary semiconductor chip device 290 which may be substantially identical to the semiconductor chip device 10 depicted and described elsewhere herein. However, the semiconductor chip device 290 has a room temperature upward warpage as shown. FIG. 12 is provided simply to illustrate that any of the disclosed embodiments of the clamping members 170, 170′, 170″, 170′″ and 170″″, etc. may be used with a circuit board that is either upwardly or downwardly warped.

The foregoing illustrative embodiments of the clamping members may be used to clamp a circuit board of a semiconductor chip device on a discrete basis. However, the skilled artisan will appreciate that the concepts of utilizing a clamping member along with an elastomeric member may be extended to a clamping device that includes multiple clamping members 170 integrally or otherwise connected as shown in FIG. 13, which is a sectional view. Here, the multiple clamping member bodies 170 are commonly joined or otherwise integrally formed and may be provided with respective connecting members or shafts 180 to facilitate z-axis movement. Each of the clamping members 170 may include a respective elastomeric member 195 configured as shown or like any of the other illustrative embodiments to enable the simultaneous clamping of multiple semiconductor chip devices such as multiple examples of the semiconductor chip device 10.

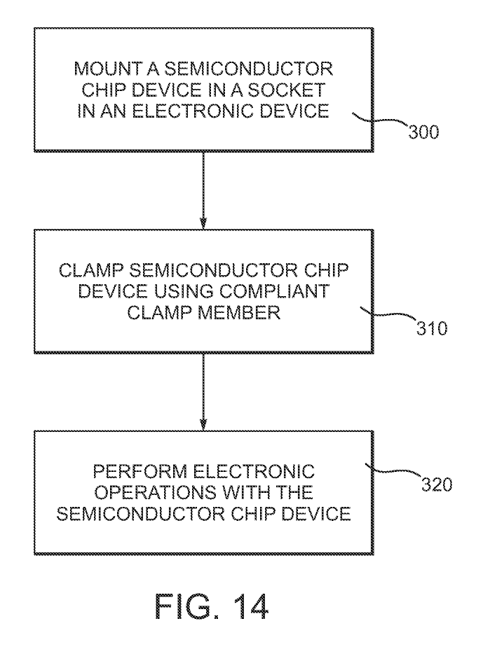

FIG. 14 depicts an exemplary flow chart for an exemplary clamping and testing process that may be performed. At step 300, a semiconductor chip device may be mounted in a socket in an electronic device, such as, for example, the socket 135 of the circuit board 140 depicted in FIG. 5. At step 310, the semiconductor chip device 10 may be clamped in the socket using any of the disclosed embodiments of a compliant clamping member 170, 170′, etc. and at step 320, electrical testing is performed, i.e., electronic operations are performed with the semiconductor chip device, such as system level testing, or any of a variety of different types of tests. Examples, whether done manually or by running various test pattens or scripts, include verifying semiconductor chip and/or board operation, floating point operations, input/output performance, continuity tests, thermal tests or the like.

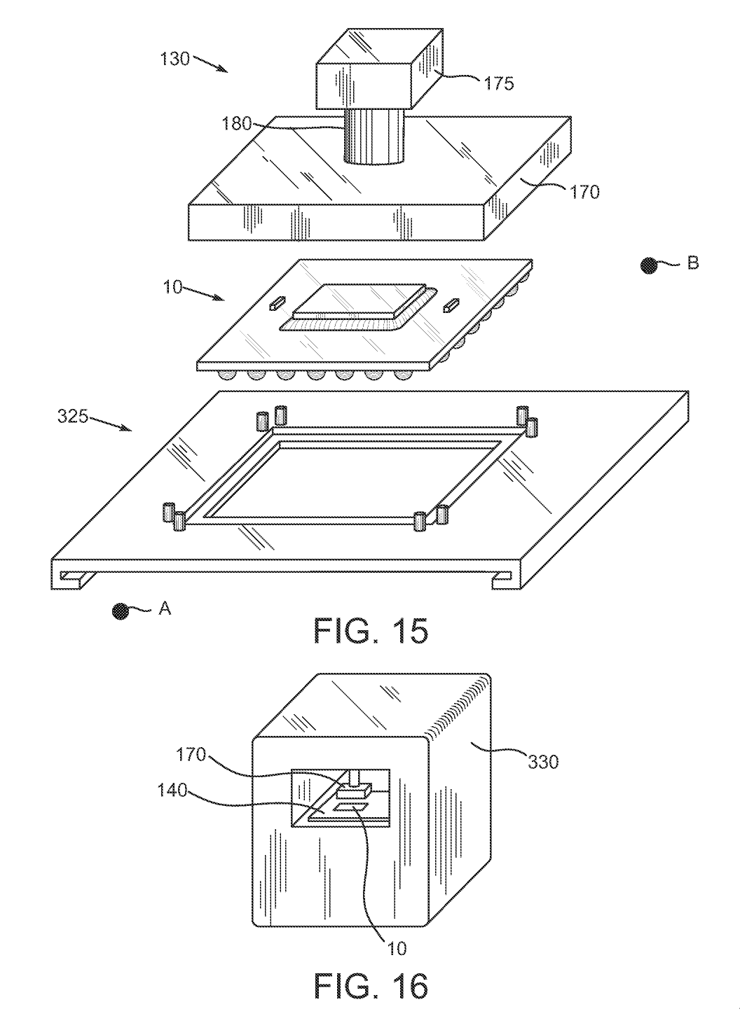

As noted elsewhere herein, any of the disclosed embodiments of the clamping mechanism 30 may be used to not only clamp a circuit board against a member like a socket but also other types of members such as a circuit board carrier or boat. In this regard, attention is now turned to FIG. 15, which is an exploded pictorial view of an embodiment of the clamping mechanism 130, the semiconductor chip device 10 and an exemplary circuit board carrier or boat 325. Here, the boat 325 may be used to transport the semiconductor chip device 10 with or without the semiconductor chip 15 or the other components 30 and 35 mounted thereon from one position to the other, say from position A to position B. This may be useful in circumstances where the circuit board 20 is undergoing either testing, component attach or other types of steps.

The clamping mechanism 130 may be used to clamp the circuit board 20 against the boat 325 by way of the clamping body 170 and operation of the actuator 175, which may be connected to the body 170 by way of the shaft 180. Of course, the skilled artisan will appreciate that other types of attachment and/or movement mechanisms may be used to hold the clamping body 170 against the circuit board 20 and ultimately the boat 325. Indeed, the boat 325 depicted in FIG. 15 is merely exemplary in that circuit board carriers can take on a sizable variety of shapes and sizes.

In addition to serving as a clamping mechanism to hold a circuit board against a carrier or boat, the clamping body 170 and any alternatives thereof may be used to clamp the semiconductor chip device 10, again with or without a semiconductor chip or other components secured thereto, to another system or test board in, for example, an automated test equipment (ATE) console 330 depicted pictorially in FIG. 16. Here, the ATE console 330 may include the circuit board 140 that, as described elsewhere herein, may be a system board, test board or other type of circuit board operable to receive and electronically interface with the semiconductor chip device 10. The clamping body 170 or in the other disclosed embodiments of the clamping body may be used to secure the semiconductor chip device 10 on the circuit board 140 within the confines of the ATE console 330. Again, the ATE console 330 may alternatively be some other type of testing instrument processing station or other.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of clamping a first circuit board against a member, the first circuit board having a first side and a second side opposite the first side, comprising:
engaging an elastomeric member of a clamping member with the first side of the first circuit board to compliantly bear against the first side of the first circuit board; and
whereby the second side of the circuit board is clamped against the member.

2. The method of claim 1, wherein the member comprises a second circuit board socket.

3. The method of claim 1, wherein the second circuit board socket comprises part of an automated test equipment.

4. The method of claim 1, wherein the member comprises a circuit board carrier.

5. The method of claim 1, wherein the elastomeric member comprises a peripheral surface with a first interior space to provide clearance for components on the first circuit board.

6. The method of claim 5, wherein the first interior space is to provide clearance for a semiconductor chip, the elastomeric member comprising a second interior space to provide clearance for other components on the first circuit board.

7. The method of claim 5, wherein the elastomeric member comprises a portion adapted to seat on semiconductor chip on the circuit board.

8. The method of claim 1, wherein the member comprises a second circuit board socket, the method comprising performing an electrical test on the first circuit board while the elastomeric member is in engagement.

9. The method of claim 1, wherein the second circuit board socket comprises plural movable pins.

10. The method of claim 1, wherein the first circuit board is substantially non-planar when the second of the first circuit board is clamped against the member.

11. A clamping member adapted to clamp a first circuit board against a member, the first circuit board having a first side and a second side opposite the first side, comprising:
a body having a first side and a second side opposite the first side; and
an elastomeric member coupled to the second side of the body and adapted to compliantly bear against the first side of the first circuit board and clamp the second side of the circuit board against the member.

12. The clamping member of claim 11, wherein the member comprises a second circuit board socket.

13. The clamping member of claim 11, wherein the second circuit board socket comprises part of an automated test equipment.

14. The clamping member of claim 11, wherein the member comprises a circuit board carrier.

15. The clamping member of claim 11, wherein the elastomeric member comprises a peripheral surface with a first interior space to provide clearance for components on the first circuit board.

16. The clamping member of claim 15, wherein the first interior space is to provide clearance for a semiconductor chip, the elastomeric member comprising a second interior space to provide clearance for other components on the first circuit board.

17. The clamping member of claim 15, wherein the elastomeric member comprises a portion adapted to seat on semiconductor chip on the circuit board.

18. An apparatus, comprising:
a first circuit board having a socket; and
a clamping member adapted to clamp a second circuit board against the socket, the clamping member including a body having a first side and a second side opposite the first side, and an elastomeric member coupled to the second of the body and adapted to compliantly bear against the first side of the first circuit board and clamp the second side of the circuit board against the member.

19. The apparatus of claim 18, wherein the first circuit board comprises a test board.

20. The apparatus of claim 19, wherein the second circuit board comprises a semiconductor chip package substrate.

21. The apparatus of claim 18, wherein the elastomeric member comprises a peripheral surface with a first interior space to provide clearance for components on the first circuit board.

22. The apparatus of claim 21, wherein the first interior space is to provide clearance for a semiconductor chip, the elastomeric member comprising a second interior space to provide clearance for other components on the first circuit board.

23. The apparatus of claim of claim 21, wherein the elastomeric member comprises a portion adapted to seat on semiconductor chip on the circuit board.
